(19) United States
(12) Patent Application Publication
(10) Pub. No.: US 2026/0182108 A1
(43) Pub. Date: Jun. 25, 2026

(54) DUAL-SIDED DISPLAY AND MANUFACTURING METHOD THEREOF

(71) Applicant: AUO Corporation, Hsinchu City (TW)

(72) Inventors: Ching-Liang Huang, Hsinchu City (TW); Chan-Jui Liu, Hsinchu City (TW); Jia-Hong Ye, Hsinchu City (TW); Shu-Hao Huang, Hsinchu City (TW); Sung-Yu Su, Hsinchu City (TW)

(73) Assignee: AUO Corporation, Hsinchu City (TW)

(21) Appl. No.: 19/212,683

(22) Filed: May 20, 2025

(30) Foreign Application Priority Data
Dec. 23, 2024 (TW) 113150132

(51) Int. Cl. H10H 29/32; H10H 29/01; H10H 29/39; H10H 29/49; H10H 29/856

(52) U.S. Cl. CPC H10H 29/32; H10H 29/012; H10H 29/39; H10H 29/49; H10H 29/856

(57) ABSTRACT

A dual-sided display including a first substrate, a circuit structure, a first pixel, and a second pixel is provided. The circuit structure is formed on the first substrate and includes a first pixel control circuit. The first pixel control circuit includes a driving transistor and first and second light-emission control transistors electrically connected to the driving transistor. The first pixel includes a first light-emitting diode. The second pixel includes a second light-emitting diode. The first light-emitting diode and the second light-emitting diode are bonded to the circuit structure and are respectively electrically connected to the first light-emission control transistor and the second light-emission control transistor. The second pixel is configured to cause the dual-sided display to emit light from a first side, and the first pixel is configured to cause the dual-sided display to emit light from a second side opposite to the first side.

### CROSS-REFERENCE TO RELATED APPLICATION

This application claims the priority benefit of Taiwan application serial no. 113150132, filed on Dec. 23, 2024. The entirety of the above-mentioned patent application is hereby incorporated by reference herein and made a part of this specification.

### BACKGROUND

### Technical Field

The disclosure relates to a dual-sided display and a manufacturing method thereof.

### Description of Related Art

Light-emitting diode (micro-LED) display devices are a novel display technology that uses light-emitting diodes of only a few micrometers in size as the light-emitting units of pixels. Light-emitting diodes possess characteristics such as high brightness, high contrast, low power consumption, and long lifespan, making them highly suitable for applications in high-resolution displays and wearable devices, while enabling ultra-thin and lightweight designs.

A dual-sided display is a device with two display surfaces, typically used for simultaneously presenting different content or providing supplemental information on the back side, such as in electronic billboards or commercial display screens. This type of display may utilize light-emitting diode technology, combining its high brightness and low energy consumption characteristics to enhance efficiency and durability in dual-sided display applications.

### SUMMARY

The disclosure provides a dual-sided display and a manufacturing method thereof. The dual-sided display enables efficient display of images on two opposite sides.

At least an embodiment of the disclosure provides a dual-sided display, which includes a first substrate, a circuit structure, a first pixel, and a second pixel. The circuit structure is formed on the first substrate and includes a first pixel control circuit. The first pixel control circuit includes a driving transistor and a first light-emission control transistor and a second light-emission control transistor electrically connected to the driving transistor. The first pixel includes a first light-emitting diode. The second pixel includes a second light-emitting diode. The first light-emitting diode and the second light-emitting diode are bonded to the circuit structure and are respectively electrically connected to the first light-emission control transistor and the second light-emission control transistor. The second pixel is configured to cause the dual-sided display to emit light from a first side, and the first pixel is configured to cause the dual-sided display to emit light from a second side opposite to the first side.

At least an embodiment of the disclosure provides a manufacturing method of a dual-sided display, which includes the following steps. A circuit structure is formed on a first substrate. The circuit structure includes a first pixel control circuit. The first pixel control circuit includes a driving transistor and a first light-emission control transistor and a second light-emission control transistor electrically connected to the driving transistor. A first light-emitting diode and a second light-emitting diode are transferred to the circuit structure. The first light-emitting diode and the second light-emitting diode are electrically connected to the first light-emission control transistor and the second light-emission control transistor, respectively. A second light-shielding layer is formed on a second substrate. A reflective layer is formed on the second substrate. The first substrate is bonded to the second substrate using an encapsulation layer. The second light-emitting diode is configured to cause the dual-sided display to emit light from a first side, and the first light-emitting diode is configured to cause the dual-sided display to emit light from a second side opposite to the first side.

### BRIEF DESCRIPTION OF THE DRAWINGS

FIG. 1 is a schematic cross-sectional view of a dual-sided display according to an embodiment of the disclosure.

FIG. 2 is a schematic cross-sectional view of a dual-sided display according to another embodiment of the disclosure.

FIG. 3 is a schematic cross-sectional view of a dual-sided display according to yet another embodiment of the disclosure.

FIGS. 4A to 4B and FIGS. 5A to 5C are schematic cross-sectional views illustrating various stages of a manufacturing method of a dual-sided display according to an embodiment of the disclosure.

FIG. 6A is a schematic cross-sectional view of a shielding layer according to an embodiment of the disclosure.

FIG. 6B is a graph showing the relationship between the average reflectivity of a shielding layer and the deposition power of a covering layer according to some embodiments of the disclosure.

FIG. 7 is a bottom perspective schematic view of a dual-sided display according to an embodiment of the disclosure.

FIG. 8A is a partial top view schematic of a dual-sided display according to an embodiment of the disclosure.

FIG. 8B is a top view schematic of the first light-emitting diode, second light-emitting diode, first bonding pad, and second bonding pad in the dual-sided display of FIG. 8A.

FIG. 9A is a partial top view schematic of a dual-sided display according to an embodiment of the disclosure.

FIG. 9B is a top view schematic of the first light-emitting diode, second light-emitting diode, first bonding pad, and second bonding pad in the dual-sided display of FIG. 9A.

FIG. 10A is an equivalent circuit diagram of the first light-emitting diode, second light-emitting diode, and the first pixel control circuit according to an embodiment of the disclosure.

FIG. 10B is an equivalent circuit diagram of the first light-emitting diode, second light-emitting diode, and the second pixel control circuit according to an embodiment of the disclosure.

FIG. 10C is an equivalent circuit diagram of the first light-emitting diode, second light-emitting diode, and the third pixel control circuit according to an embodiment of the disclosure.

FIG. 11 is a timing diagram illustrating a driving method for a light-emitting diode according to an embodiment of the disclosure.

### DESCRIPTION OF THE EMBODIMENTS

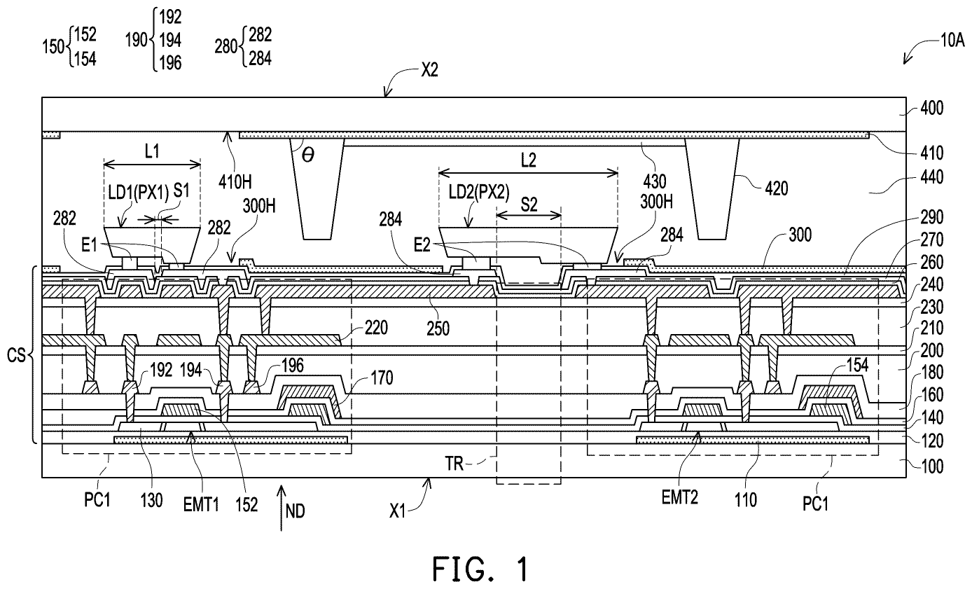

FIG. 1 is a schematic cross-sectional view of a dual-sided display 10A according to an embodiment of the disclosure. Referring to FIG. 1, the dual-sided display 10A includes a first substrate 100, a second substrate 400, a circuit structure CS, a reflective layer 430, multiple first pixels PX1 (only one of which is shown in FIG. 1), multiple second pixels PX2 (only one of which is shown in FIG. 1), and an isolation structure 420.

The second substrate 400 overlaps the first substrate 100. The first substrate 100 and the second substrate 400 are transparent substrates, and the materials include glass, organic materials, or other suitable materials. Organic materials include, for example, polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU), or other suitable materials. The first substrate 100 and the second substrate 400 may be rigid substrates, flexible substrates, or stretchable substrates.

The circuit structure CS is formed on the first substrate 100. The circuit structure CS includes a semiconductor layer, a conductive layer, and an insulating layer, where the number of each layer may be adjusted as needed. In this embodiment, the circuit structure CS includes a shielding layer 110, a buffer layer 120, a semiconductor layer 130, a gate dielectric layer 140, a first conductive layer 150, a dielectric layer 160, a second conductive layer 170, an interlayer dielectric layer 180, a third conductive layer 190, a first planarization layer 200, a first insulating layer 210, a fourth conductive layer 220, a second planarization layer 230, a second insulating layer 240, a fifth conductive layer 250, a third insulating layer 260, a fourth insulating layer 270, a sixth conductive layer 280, a fifth insulating layer 290, and a first light-shielding layer 300.

The shielding layer 110 is formed on the first substrate 100. In this embodiment, the shielding layer 110 directly contacts the first substrate 100, but the disclosure is not limited thereto. In other embodiments, additional insulating layers may be included between the shielding layer 110 and the first substrate 100. The shielding layer 110 is used to block ambient light to prevent it from interfering with electronic components in the circuit structure CS. In some embodiments, the material of the shielding layer 110 includes metals, metal oxides, or combinations thereof, or other suitable materials. In some embodiments, the thickness of the shielding layer 110 ranges from 900 Å to 8000 Å.

The buffer layer 120 is located on the shielding layer 110 and the first substrate 100 and includes insulating materials. In some embodiments, the buffer layer 120 may have a single-layer or multi-layer structure.

Multiple semiconductor layers 130 are located on the buffer layer 120. The semiconductor layer 130 has a single-layer or multi-layer structure, and the materials include amorphous silicon, polysilicon, microcrystalline silicon, monocrystalline silicon, organic semiconductor materials, oxide semiconductor materials (e.g., indium zinc oxide, indium gallium zinc oxide, or combinations of these materials), or other suitable materials or combinations of these materials. In some embodiments, the semiconductor layer 130 includes doped regions and channel regions, where the doped regions may further include lightly doped regions and heavily doped regions. In some embodiments, the semiconductor layer 130 is formed using a low-temperature polysilicon process.

The gate dielectric layer 140 is located on the semiconductor layer 130. The first conductive layer 150 is located on the gate dielectric layer 140. The first conductive layer 150 includes multiple gates 152 and conductive features 154. Each of the gate 152 overlaps a corresponding channel region of the semiconductor layer 130. The conductive features 154 include, for example, electrodes, signal lines, or other conductive structures.

The dielectric layer 160 is located on the first conductive layer 150. The second conductive layer 170 is located on the dielectric layer 160. The second conductive layer 170 includes, for example, electrodes, signal lines, or other conductive structures.

The interlayer dielectric layer 180 is located on the second conductive layer 170 and the dielectric layer 160. The third conductive layer 190 is located on the interlayer dielectric layer 180. The third conductive layer 190 includes multiple sources/drains 192 and 194 and conductive features 196. The sources/drains 192 and 194 are electrically connected to the corresponding doped regions of the semiconductor layer 130. The conductive features 196 include, for example, electrodes, signal lines, or other conductive structures. In some embodiments, the thickness of the interlayer dielectric layer 180 is 2000 Å to 5000 Å. In some embodiments, the material of the interlayer dielectric layer 180 is silicon nitride or other suitable materials.

In this embodiment, one semiconductor layer 130 and the corresponding gate 152 and sources/drains 192 and 194 form a first transistor EMT1 (or the first light-emission control transistor), and another semiconductor layer 130 and the corresponding gate 152 and sources/drains 192 and 194 form a second transistor EMT2 (or the second light-emission control transistor).

In this embodiment, the circuit structure CS includes a first pixel control circuit PC1, wherein the first pixel control circuit PC1 includes the first transistor EMT1 and the second transistor EMT2. In some embodiments, the first pixel control circuit PC1 may further include other transistors and passive components (e.g., capacitors, resistors, inductors, etc.), and these transistors and passive components cooperate to drive the light-emitting diodes. In this embodiment, one pixel control circuit is configured to control two light-emitting diodes, including an upward-emitting light-emitting diode and a downward-emitting light-emitting diode.

In this embodiment, the first transistor EMT1 and the second transistor EMT2 are top-gate thin-film transistors, but the disclosure is not limited thereto. In other embodiments, the first transistor EMT1 and the second transistor EMT2 may include bottom-gate thin-film transistors, double-gate thin-film transistors, or other types of thin-film transistors. Additionally, the first pixel control circuit PC1 may include one type or multiple types of transistors.

The shielding layer 110 overlaps the first transistor EMT1 and the second transistor EMT2 in a normal direction ND of the top surface of the first substrate 100, preventing ambient light from a first side X1 of the dual-sided display 10A from irradiating the semiconductor layer 130, which could cause leakage or transistor degradation.

The first planarization layer 200 and the first insulating layer 210 are located on the second conductive layer 170 and the interlayer dielectric layer 180, and the first planarization layer 200 and the first insulating layer 210 include, for example, different insulating materials.

The fourth conductive layer 220 is located on the first insulating layer 210 and passes through the first planarization layer 200 and the first insulating layer 210 to electrically connect to the third conductive layer 190. In this embodiment, the first insulating layer 210 is only located on the top surface of the first planarization layer 200, but the disclosure is not limited thereto. In other embodiments, the first insulating layer 210 fills the through via of the first planarization layer 200 and surrounds the portion of the fourth conductive layer 220 connected to the third conductive layer 190.

The second planarization layer 230 and the second insulating layer 240 are located on the fourth conductive layer 220 and the first insulating layer 210, and the second planarization layer 230 and the second insulating layer 240 include, for example, different insulating materials.

The fifth conductive layer 250 is located on the second insulating layer 240 and passes through the second planarization layer 230 and the second insulating layer 240 to electrically connect to the fourth conductive layer 220. In this embodiment, the second insulating layer 240 is only located on the top surface of the second planarization layer 230, but the disclosure is not limited thereto. In other embodiments, the second insulating layer 240 fills the through via of the second planarization layer 230 and surrounds the portion of the fifth conductive layer 250 connected to the fourth conductive layer 220.

In some embodiments, the thickness of each of the first planarization layer 200 and the second planarization layer 230 is 1 μm to 5 μm, but the disclosure is not limited thereto.

The third insulating layer 260 and the fourth insulating layer 270 are located on the fifth conductive layer 250 and the second insulating layer 240. The sixth conductive layer 280 is located on the fourth insulating layer 270. In some embodiments, the third insulating layer 260 may be omitted.

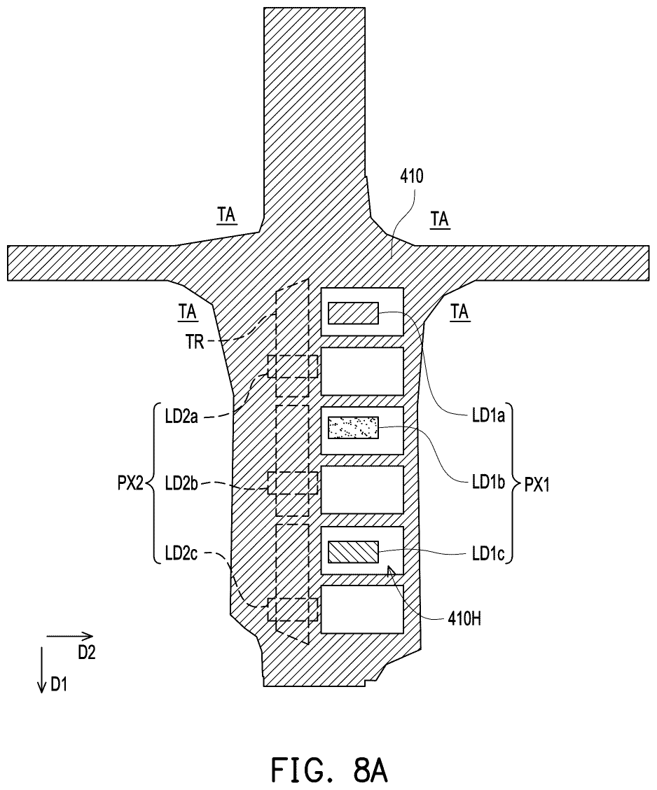

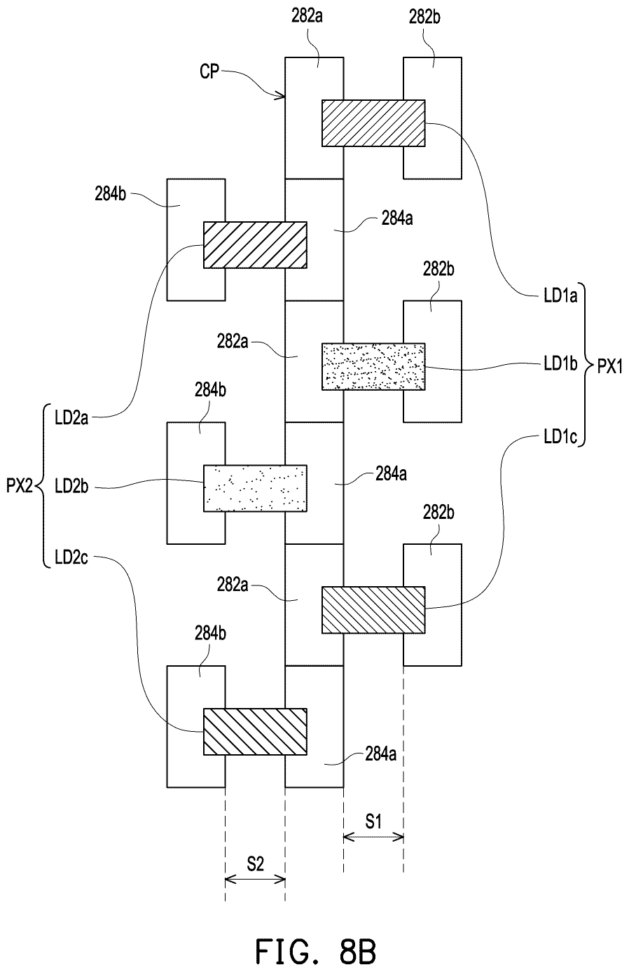

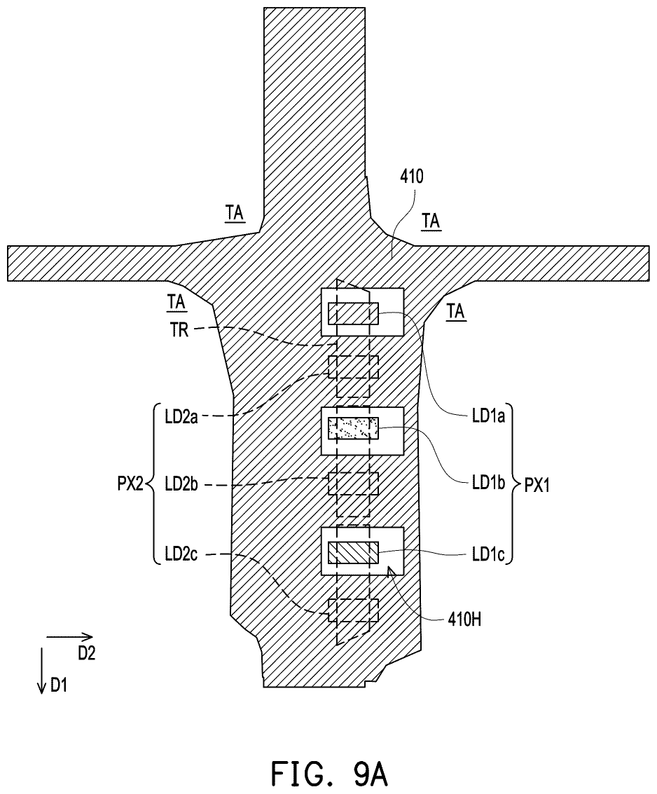

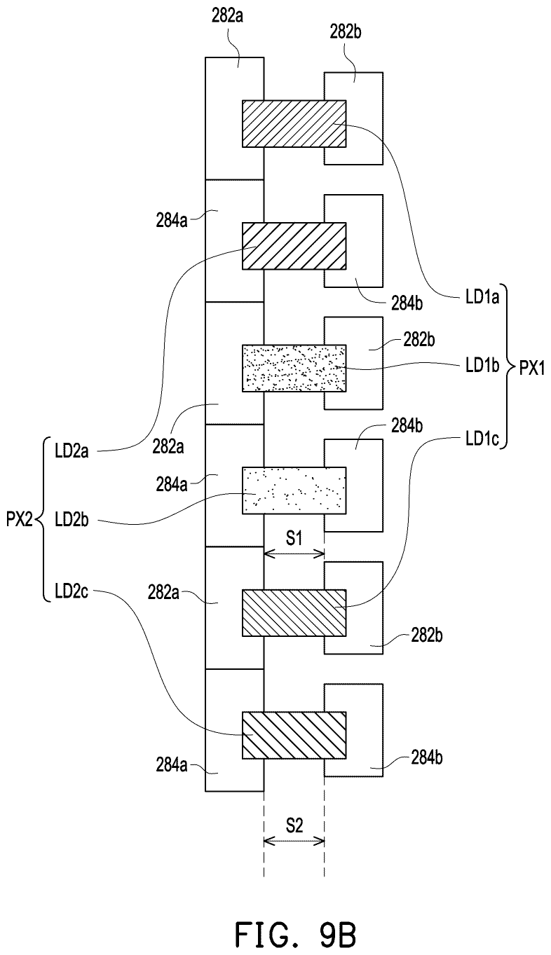

The sixth conductive layer 280 includes, for example, multiple first bonding pads 282 and multiple second bonding pads 284. In this embodiment, one of the first bonding pads 282 is electrically connected to the source/drain 194 of the first transistor EMT1 through the fifth conductive layer 250 and the fourth conductive layer 220, while another first bonding pad 282 is electrically connected to an operating voltage signal line (or a shared signal line), wherein the operating voltage signal line may be located in any of the first conductive layer 150 to the fourth conductive layer 220. Similarly, one of the second bonding pads 284 is electrically connected to the source/drain 194 of the second transistor EMT2 through the fifth conductive layer 250 and the fourth conductive layer 220, while another second bonding pad 284 is also electrically connected to the operating voltage signal line (or the shared signal line). In some embodiments, the first bonding pad 282 and the second bonding pad 284 that are electrically connected to the shared signal line may be integrated into one (refer to FIGS. 8B and 9B).

The fifth insulating layer 290 is located on the sixth conductive layer 280 and the fourth insulating layer 270.

The first light-shielding layer 300 is located on the fifth insulating layer 290. In some embodiments, the first light-shielding layer 300 may also be referred to as a black matrix, and its transmittance for visible light is, for example, less than 1%. The first light-shielding layer 300 has multiple first openings 300H. The material of the first light-shielding layer 300 includes metals, metal oxides, black resin, combinations thereof, or other suitable materials. In some embodiments, the first light-shielding layer 300 and the shielding layer 110 may include the same or different materials.

In this embodiment, the first light-shielding layer 300 is located on the top surface of the circuit structure CS, but the disclosure is not limited thereto. In some embodiments, the first light-shielding layer 300 is located between the third insulating layer 260 and the fourth insulating layer 270.

The first pixel PX1 includes a first light-emitting diode LD1 bonded to the circuit structure CS. Two first electrodes E1 of the first light-emitting diode LD1 are bonded to two first bonding pads 282 of the circuit structure CS. For example, the first electrodes E1 are bonded to the first bonding pads 282 using solder, conductive adhesive, or other conductive bonding materials. In some embodiments, the first pixel PX1 includes more than one first light-emitting diode LD1, and these first light-emitting diodes LD1 may be light-emitting diodes of different colors (e.g., a first red light-emitting diode, a first green light-emitting diode, and a first blue light-emitting diode), enabling the dual-sided display 10A to display a color image.

The second pixel PX2 includes a second light-emitting diode LD2 bonded to the circuit structure CS. Two second electrodes E2 of the second light-emitting diode LD2 are bonded to two second bonding pads 284 of the circuit structure CS. For example, the second electrodes E2 are bonded to the second bonding pads 284 using solder, conductive adhesive, or other conductive bonding materials. In some embodiments, the second pixel PX2 includes more than one second light-emitting diode LD2, and these second light-emitting diodes LD2 may be light-emitting diodes of different colors (e.g., a second red light-emitting diode, a second green light-emitting diode, and a second blue light-emitting diode), enabling the dual-sided display 10A to display a color image.

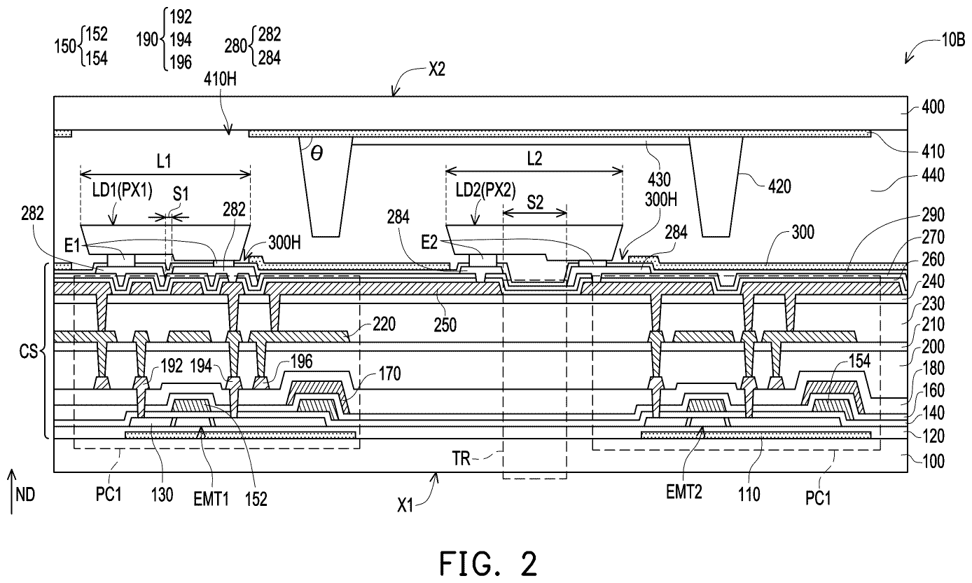

In this embodiment, the first light-emitting diode LD1 and the second light-emitting diode LD2 may have different sizes. For example, a length L1 of the first light-emitting diode LD1 may differ from a length L2 of the second light-emitting diode LD2. However, the disclosure is not limited thereto. In other embodiments, the first light-emitting diode LD1 and the second light-emitting diode LD2 may have the same size, as shown in a dual-sided display 10B of FIG. 2, where the length L1 of the first light-emitting diode LD1 equals the length L2 of the second light-emitting diode LD2. In some embodiments, the size of the first red light-emitting diode of the first pixel PX1 may be the same as or different from the size of the second red light-emitting diode of the second pixel PX2, the size of the first green light-emitting diode of the first pixel PX1 may be the same as or different from the size of the second green light-emitting diode of the second pixel PX2, and the size of the first blue light-emitting diode of the first pixel PX1 may be the same as or different from the size of the second blue light-emitting diode of the second pixel PX2.

A second light-shielding layer 410 is formed on the second substrate 400. In this embodiment, the second light-shielding layer 410 is in direct contact with the second substrate 400, but the disclosure is not limited thereto. In other embodiments, additional insulating layers may be included between the second light-shielding layer 410 and the second substrate 400. In some embodiments, the second light-shielding layer 410 may also be referred to as a black matrix, and its transmittance for visible light is, for example, less than 1%. The second light-shielding layer 410 has multiple second openings 410H. In some embodiments, the material of the second light-shielding layer 410 includes metals, metal oxides, black resin, combinations thereof, or other suitable materials. In some embodiments, the second light-shielding layer 410 and the shielding layer 110 may include the same or different materials.

The isolation structure 420 and the reflective layer 430 are formed on the second substrate 400. In some embodiments, the isolation structure 420 and the reflective layer 430 are located on the second light-shielding layer 410, wherein the first light-shielding layer 300 is located between the first substrate 100 and the isolation structure 420, and the second light-shielding layer 410 is located between the isolation structure 420 and the second substrate 400.

The first pixel PX1 and the second pixel PX2 are surrounded by the isolation structure 420. In some embodiments, the first light-emitting diode LD1 in the first pixel PX1 and the second light-emitting diode LD2 in the second pixel PX2 are surrounded by the isolation structure 420. The isolation structure 420 separates the first pixel PX1 and the second pixel PX2 laterally, reducing the likelihood of mutual interference between the first pixel PX1 and the second pixel PX2.

In some embodiments, the isolation structure 420 includes reflective materials and has high reflectivity and low transmittance. In some embodiments, the transmittance of the isolation structure 420 for visible light is less than 10%, and the optical density (OD) of the isolation structure 420 is greater than 1. In some embodiments, the angle θ between the bottom surface and the side surface of the isolation structure 420 is 60 degrees to 90 degrees. In some embodiments, the thickness of the isolation structure 420 is 5 μm to 30 μm. In some embodiments, the thickness of the isolation structure 420 is 10 μm to 30 μm.

In some embodiments, the material of the reflective layer 430 includes silver, aluminum, combinations thereof, or other suitable materials.

The encapsulation layer 440 is located between the first substrate 100 and the second substrate 400 and encapsulates the first light-emitting diode LD1 and the second light-emitting diode LD2. In some embodiments, the encapsulation layer 440 includes optical adhesive or other suitable materials.

The first pixel PX1 is configured to cause a second side X2 of the dual-sided display 10A to emit light. More specifically, the first light-emitting diode LD1 is configured to cause the second side X2 of the dual-sided display 10A to emit light, and the circuit structure CS is configured to at least partially shield the light emitted by the first light-emitting diode LD1 toward the first substrate 100. For example, one or more light-shielding structures in the circuit structure CS overlap a gap between the two first bonding pads 282 in the normal direction ND of the top surface of the first substrate 100 (indicated as a distance S1 between the two first bonding pads 282 in FIG. 1). The light emitted by the first light-emitting diode LD1 toward the first substrate 100 enters the circuit structure CS through the gap between the two first bonding pads 282, and more than 80% of the gap between the two first bonding pads 282 in the normal direction ND is shielded by one or more light-shielding structures, preferably 100% shielded.

In some embodiments, the one or more light-shielding structures, such as the shielding layer 110, the semiconductor layer 130, the first conductive layer 150, the second conductive layer 170, the third conductive layer 190, the fourth conductive layer 220, the fifth conductive layer 250, or the sixth conductive layer 280, overlap a portion of the first light-emitting diode LD1, preventing the light emitted by the first light-emitting diode LD1 from exiting through the first side X1 of the dual-sided display 10A. The light-shielding structures include, for example, signal lines, electrodes, or other similar elements in the circuit structure CS.

The second pixel PX2 is configured to cause the first side X1 of the dual-sided display 10A to emit light. More specifically, the second light-emitting diode LD2 is configured to cause the first side X1 of the dual-sided display 10A to emit light. The reflective layer 430 is configured to reflect the light emitted by the second light-emitting diode LD2 toward the second substrate 400. The light emitted by the second light-emitting diode LD2 toward the first substrate 100 enters the circuit structure CS through the gap between the two second bonding pads 284 (indicated as a distance S2 between the two second bonding pads 284 in FIG. 1). The gap between the two second bonding pads 284 overlaps a transparent region TR of the circuit structure CS, allowing the light emitted by the second light-emitting diode LD2 to exit through the first side X1 of the dual-sided display 10A.

In some embodiments, to increase the light-emitting area of the second light-emitting diode LD2 emitting light downward, the length L2 of the second light-emitting diode LD2 is made greater than the length L1 of the first light-emitting diode LD1. Due to the increased length L2, the distance S2 between the two second bonding pads 284 may also be increased, thereby enhancing the brightness of the image on the first side X1 of the dual-sided display 10A. In some embodiments, the distance S1 between the two first bonding pads 282 is less than the distance S2 between the two second bonding pads 284. In some embodiments, the ratio of the distance S2 between the two second bonding pads 284 to the length L2 of the second light-emitting diode LD2 is less than 1 and greater than 0.3.

In some embodiments, the multiple first openings 300H of the first light-shielding layer 300 respectively overlap the first light-emitting diode LD1 and the second light-emitting diode LD2. In some embodiments, the size of the first opening 300H overlapping the first light-emitting diode LD1 may be the same as or different from the size of the first opening 300H overlapping the second light-emitting diode LD2.

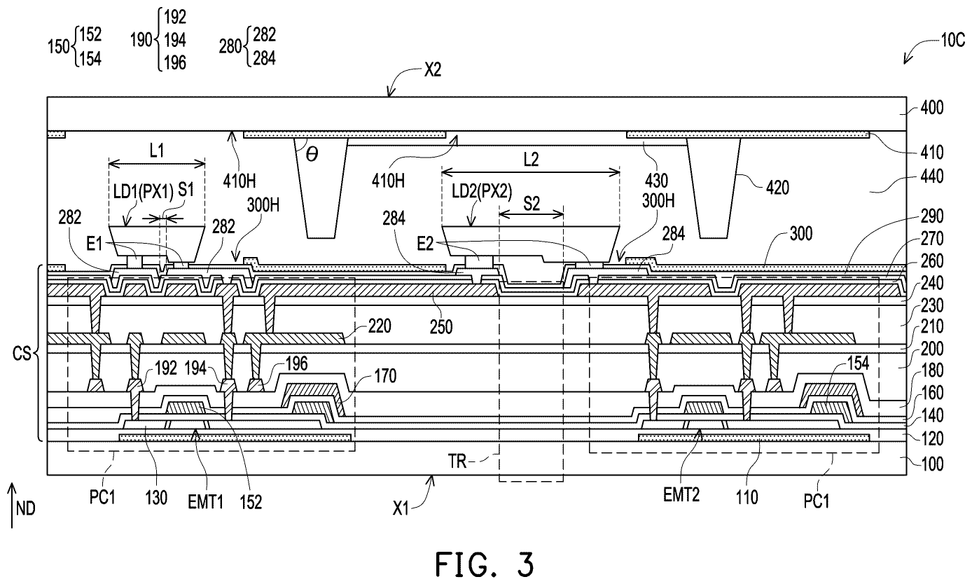

In some embodiments, at least a portion of the second openings 410H of the second light-shielding layer 410 overlaps the first light-emitting diode LD1. In this embodiment, the second opening 410H overlaps the first light-emitting diode LD1 but does not overlap the second light-emitting diode LD2. The second light-shielding layer 410 extends between the reflective layer 430 and the second substrate 400 and overlaps the reflective layer 430 and the second light-emitting diode LD2. However, the disclosure is not limited thereto. In other embodiments, multiple second openings 410H of the second light-shielding layer 410 overlap both the first light-emitting diode LD1 and the second light-emitting diode LD2, as shown in a dual-sided display 10C of FIG. 3. In the dual-sided display 10C, a portion of the second openings 410H overlaps the second light-emitting diode LD2, and the reflective layer 430 extends into the second openings 410H. In the dual-sided display 10C, the size of the second opening 410H overlapping the first light-emitting diode LD1 may be the same as or different from the size of the second opening 410H overlapping the second light-emitting diode LD2.

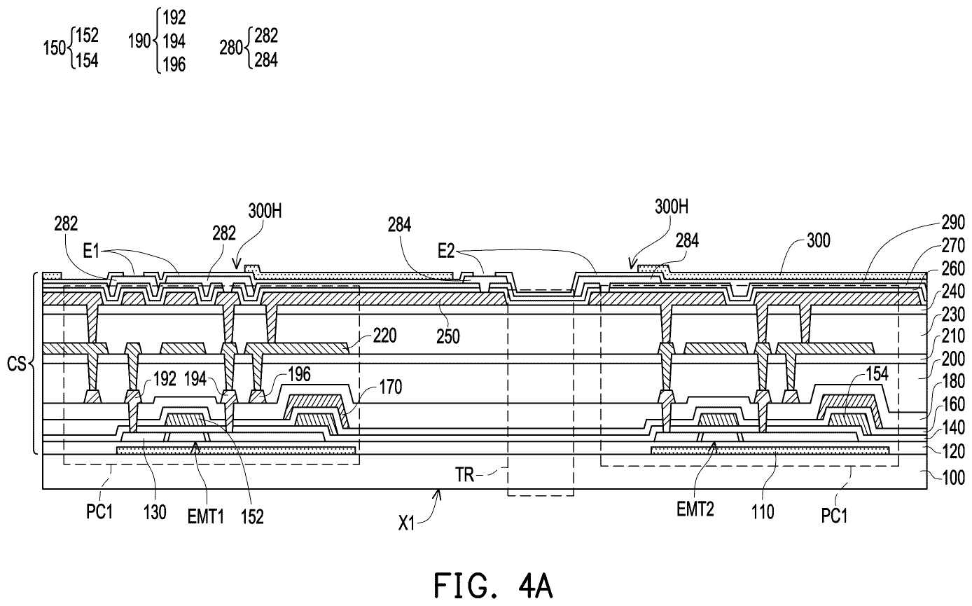

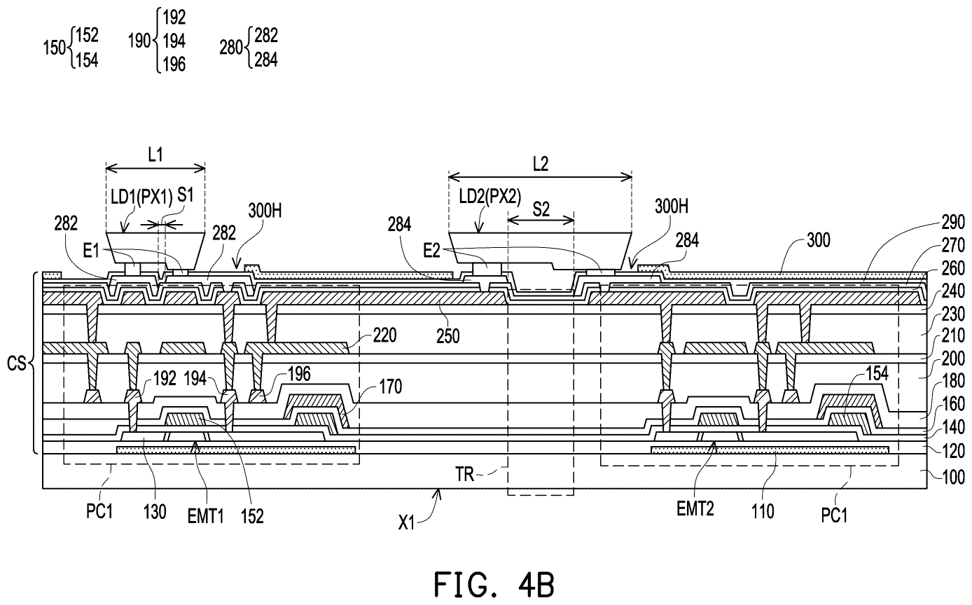

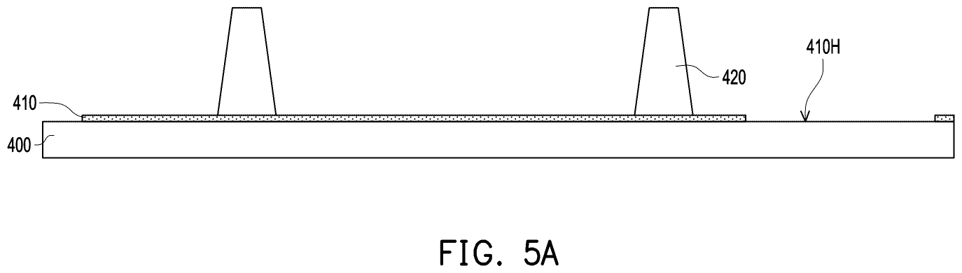

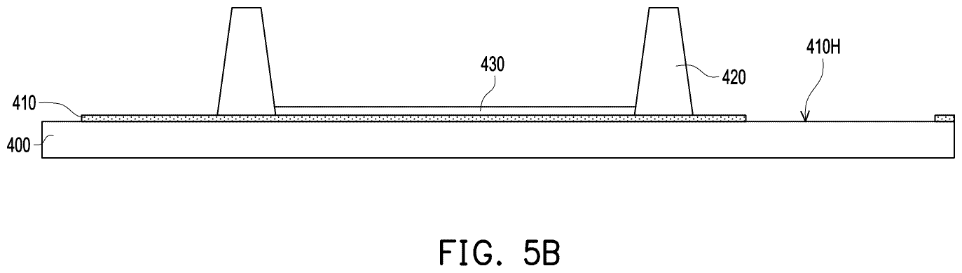

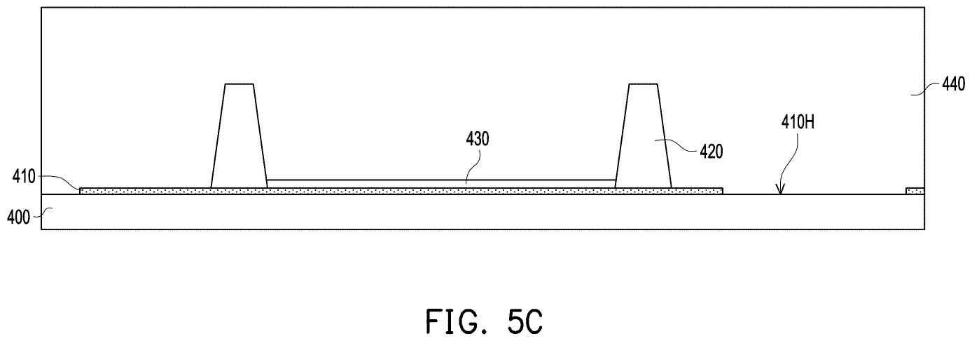

FIGS. 4A to 4B and FIGS. 5A to 5C are schematic cross-sectional views showing various stages of the manufacturing method of the dual-sided display 10A of FIG. 1. FIGS. 4A to 4B illustrate the processes on the first substrate 100, while FIGS. 5A to 5C illustrate the processes on the second substrate 400.

Referring to FIG. 4A, the circuit structure CS is formed on the first substrate 100.

Referring to FIG. 4B, the first light-emitting diode LD1 and the second light-emitting diode LD2 are transferred onto the circuit structure CS through one or more mass transfer processes.

Referring to FIG. 5A, the second light-shielding layer 410 is formed on the second substrate 400. For example, the second light-shielding layer 410 is formed through a printing process or other suitable processes. In some embodiments, a black material layer (e.g., metal, oxide, resin, etc.) is coated or deposited on the second substrate 400, followed by patterning the black material layer through a photolithography or etching process to obtain the second light-shielding layer 410.

After forming the second light-shielding layer 410, the isolation structure 420 is formed on the second substrate 400. For example, black ink is first applied to the second substrate 400 and the second light-shielding layer 410, followed by forming the isolation structure 420 with high step height using an embossing mold or roller. The embossing mold may provide greater flexibility in creating different geometric shapes to adjust the viewing angle of the dual-sided display.

Referring to FIG. 5B, the reflective layer 430 is formed using inkjet printing or other suitable methods. The reflective layer 430 includes, for example, silver paste or other suitable materials.

Referring to FIG. 5C, the encapsulation layer 440 is formed on the second substrate 400. The structure shown in FIG. 5C is then bonded to the structure shown in FIG. 4B using the encapsulation layer 440 to obtain the dual-sided display 10A shown in FIG. 1. For example, the structure shown in FIG. 5C is bonded to the structure shown in FIG. 4B through a lamination process or other suitable processes.

In some embodiments, after forming the encapsulation layer 440, a cutting process is performed to cut the structure shown in FIG. 5C to a suitable size, but the disclosure is not limited thereto.

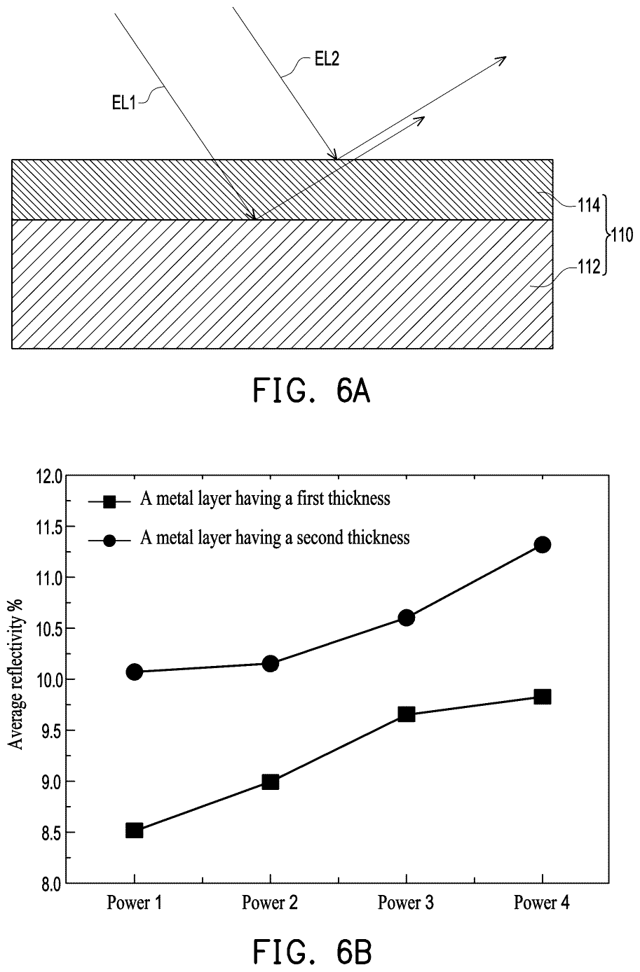

FIG. 6A is a schematic cross-sectional view of a shielding layer 110 according to an embodiment of the disclosure. For example, the shielding layer 110 in FIGS. 1 to 3 may be replaced by the shielding layer 110 in FIG. 6A. Referring to FIG. 6A, the shielding layer 110 includes a metal layer 112 and a covering layer 114. The metal layer 112 includes, for example, molybdenum or other suitable materials, and its thickness is 500 Å to 1500 Å. The covering layer 114 includes, for example, NbSiCOx, CrOx, TiOx, MoOxTa, or other suitable materials or combinations thereof. In some embodiments, the thickness of the covering layer 114 is 300 Å to 800 Å.

An external ambient light EL1 reflected from the surface of the metal layer 112 interferes destructively with an external ambient light EL2 reflected from the surface of the covering layer 114, thereby achieving the purpose of reducing reflected light. In some embodiments, the shielding layer 110 is located on the first substrate 100, and the covering layer 114 is located on the side of the metal layer 112 facing the first substrate 100 (refer to FIG. 1). Thus, the reflected light generated by the external ambient light entering from the first side X1 may be reduced.

Table 1 shows the optical density and average reflectivity of the shielding layer 110 obtained by adjusting the material and thickness of the shielding layer 110 according to some embodiments.

TABLE 1

| | | | Optical | |
|---|---|---|---|---|
| | Material of | | density | Average |
| | shielding layer | Thickness | (OD) | reflectivity |
| Embodiment 1 | Combination of | 1000 Å | 2.3 | 7.1% |
| Embodiment 2 | molybdenum | 2000 Å | 5.4 | 8.5% |
| Embodiment 3 | and MoOx | 3500 Å | 7.2 | 9.2% |
| Embodiment 4 | Black resin | Approximately | 4~4.2 | 7.4% |
| | | 1 (μm) | | |

FIG. 6B is a graph showing the relationship between the average reflectivity of the shielding layer and the deposition power of the covering layer according to some embodiments of the disclosure. Referring to FIGS. 6A and 6B, the shielding layer 110 includes a metal layer 112 (with the material being molybdenum) and a covering layer 114 (with the material being MoOx). In FIG. 6B, the first thickness is less than the second thickness, where the first thickness is 450 Å, and the second thickness is 550 Å.

In the embodiment of FIG. 6B, the covering layer 114 is deposited using an MoOx process, and the average reflectivity of the shielding layer 110 is adjusted by varying the deposition power used during the MoOx process. In FIG. 6B, power levels 1, 2, 3, and 4 increase sequentially.

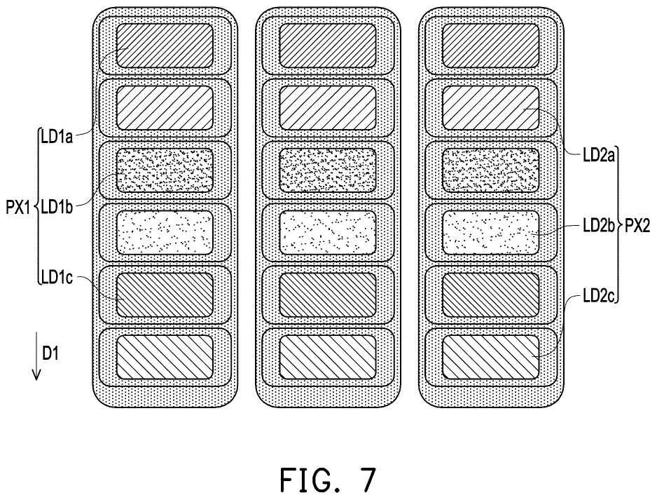

FIG. 7 is a bottom perspective schematic view of a dual-sided display according to an embodiment of the disclosure. It should be noted that the embodiment in FIG. 7 adopts the element numerals and some content from the embodiment in FIG. 1, where the same or similar numerals denote the same or similar elements, and the description of identical technical content is omitted. For omitted descriptions, refer to the previously mentioned embodiments, which are not repeated here.

Referring to FIG. 7, in this embodiment, the first pixel PX1 includes multiple first light-emitting diodes LD1a, LD1b, and LD1c. For example, the first light-emitting diodes LD1a, LD1b, and LD1c are respectively a first red light-emitting diode, a first green light-emitting diode, and a first blue light-emitting diode.

The second pixel PX2 includes multiple second light-emitting diodes LD2a, LD2b, and LD2c. For example, the second light-emitting diodes LD2a, LD2b, and LD2c are respectively a second red light-emitting diode, a second green light-emitting diode, and a second blue light-emitting diode. In this embodiment, the first light-emitting diode LD1a is adjacent to the second light-emitting diode LD2a, the first light-emitting diode LD1b is adjacent to the second light-emitting diode LD2b, and the first light-emitting diode LD1c is adjacent to the second light-emitting diode LD2c. Arranging light-emitting diodes with adjacent emission peak wavelengths next to each other helps to reduce interference between different colors.

The first light-emitting diode LD1a and the second light-emitting diode LD2a may be identical or different red light-emitting diodes. The first light-emitting diode LD1b and the second light-emitting diode LD2b may be identical or different green light-emitting diodes. The first light-emitting diode LD1c and the second light-emitting diode LD2c may be identical or different blue light-emitting diodes. For example, the first light-emitting diode and the corresponding second light-emitting diode may be identical or different in size, structure, and/or emission peak wavelength.

In this embodiment, the first light-emitting diodes LD1a, LD1b, and LD1c are configured to cause the second side of the dual-sided display to emit light, while the second light-emitting diodes LD2a, LD2b, and LD2c are configured to cause the first side of the dual-sided display to emit light. In this embodiment, the light-emitting diodes that emit light toward the first side and the light-emitting diodes that emit light toward the second side are arranged in an interleaved manner along the first direction D1.

FIG. 8A is a partial top view schematic of a dual-sided display according to an embodiment of the disclosure. FIG. 8B is a top view schematic of the first light-emitting diodes LD1a, LD1b, and LD1c, the second light-emitting diodes LD2a, LD2b, and LD2c, the first bonding pads 282a and 282b, and the second bonding pads 284a and 284b in the dual-sided display of FIG. 8A. FIG. 8A shows the second light-shielding layer 410, the first light-emitting diodes LD1a, LD1b, and LD1c, the second light-emitting diodes LD2a, LD2b, and LD2c, the transparent region TR, and a transmission region TA in the dual-sided display, while omitting other components. It should be noted that the embodiment of FIG. 8A adopts the element numerals and some content from the embodiment in FIG. 7, where the same or similar numerals denote the same or similar elements, and the description of identical technical content is omitted. For omitted descriptions, refer to the previously mentioned embodiments, which are not repeated here.

Referring to FIG. 8A, in this embodiment, the dual-sided display is a transparent display including multiple transmission regions TA. For example, opaque materials in the dual-sided display (such as scan lines, data lines, light-emission signal lines, electrodes, light-emitting diodes, pixel control circuits, etc.) are located in non-transmission regions, while light may pass through the transmission regions TA, allowing users to see the environment behind the dual-sided display through the transmission regions TA. In this embodiment, adjacent four of the transmission regions TA surround the first pixel PX1 and the second pixel PX2 in an arrangement.

The first pixel PX1 includes multiple first light-emitting diodes LD1a, LD1b, and LD1c. The second pixel PX2 includes multiple second light-emitting diodes LD2a, LD2b, and LD2c. The first light-emitting diode LD1a (e.g., a first red light-emitting diode), the second light-emitting diode LD2a (e.g., a second red light-emitting diode), the first light-emitting diode LD1b (e.g., a first green light-emitting diode), the second light-emitting diode LD2b (e.g., a second green light-emitting diode), the first light-emitting diode LD1c (e.g., a first blue light-emitting diode), and the second light-emitting diode LD2c (e.g., a second blue light-emitting diode) are arranged in an interleaved manner without a specific order.

For example, the first light-emitting diodes LD1a, LD1b, and LD1c are arranged in a column along the first direction D1, while the second light-emitting diodes LD2a, LD2b, and LD2c are arranged in another column along the first direction D1. The first light-emitting diodes LD1a, LD1b, and LD1c are staggered with the second light-emitting diodes LD2a, LD2b, and LD2c in the second direction D2, which is perpendicular to the first direction D1.

The first light-emitting diodes LD1a, LD1b, and LD1c overlap the second openings 410H of the second light-shielding layer 410. Therefore, the light emitted by the first light-emitting diodes LD1a, LD1b, and LD1c may pass through the second openings 410H, causing the dual-sided display to emit light from the second side. The second light-emitting diodes LD2a, LD2b, and LD2c overlap the transparent region TR of the circuit structure. Therefore, the light emitted by the second light-emitting diodes LD2a, LD2b, and LD2c may pass through the transparent region TR of the circuit structure, causing the dual-sided display to emit light from the first side.

Referring to FIG. 8B, the circuit structure includes multiple first bonding pads 282a and 282b and multiple second bonding pads 284a and 284b. A portion of the first bonding pads 282a and 282b (i.e., the first bonding pad 282a) is connected to a portion of the second bonding pads 284a and 284b (i.e., the second bonding pad 284a) to form a shared bonding pad CP. Another portion of the first bonding pads 282a and 282b (i.e., the first bonding pad 282b) and another portion of the second bonding pads 284a and 284b (i.e., the second bonding pad 284b) are distributed on both sides of the shared bonding pad CP.

The first light-emitting diodes LD1a, LD1b, and LD1c are respectively bonded to corresponding ones of the first bonding pads 282b, and the second light-emitting diodes LD2a, LD2b, and LD2c are respectively bonded to corresponding ones of the second bonding pads 284b. The first light-emitting diodes LD1a, LD1b, and LD1c and the second light-emitting diodes LD2a, LD2b, and LD2c are all bonded to the shared bonding pad CP.

The distance S1 between the two first bonding pads 282a and 282b bonded to the same first light-emitting diode LD1a, LD1b, LD1c and the distance S2 between the two second bonding pads 284a and 284b bonded to the same second light-emitting diode LD2a, LD2b, LD2c may be the same or different. In a preferred embodiment, the distance S2 is greater than the distance S1, making it easier for the light emitted by the second light-emitting diodes LD2a, LD2b, and LD2c to pass through the circuit structure located beneath them.

FIG. 9A is a partial top view schematic of a dual-sided display according to an embodiment of the disclosure. FIG. 9B is a top view schematic of the first light-emitting diodes LD1a, LD1b, and LD1c, the second light-emitting diodes LD2a, LD2b, and LD2c, the first bonding pads 282a and 282b, and the second bonding pads 284a and 284b in the dual-sided display of FIG. 9A. FIG. 9A shows the second light-shielding layer 410, the first light-emitting diodes LD1a, LD1b, and LD1c, the second light-emitting diodes LD2a, LD2b, and LD2c, the transparent region TR, and the transmission region TA, while omitting other components. It should be noted that the embodiment of FIG. 9A adopts the element numerals and some content from the embodiment in FIG. 7, where the same or similar numerals denote the same or similar elements, and the description of identical technical content is omitted. For omitted descriptions, refer to the previously mentioned embodiments, which are not repeated here.

Referring to FIG. 9A, in this embodiment, the dual-sided display is a transparent display including multiple transmission regions TA. For example, opaque materials in the dual-sided display (such as wires, electrodes, light-emitting diodes, pixel control circuits, etc.) are located in non-transmission regions, while light may pass through the transmission regions TA, allowing users to see the environment behind the dual-sided display through the transmission regions TA. In this embodiment, adjacent four of the transmission regions TA surround the first pixel PX1 and the second pixel PX2 in an arrangement.

The first pixel PX1 includes multiple first light-emitting diodes LD1a, LD1b, and LD1c. The second pixel PX2 includes multiple second light-emitting diodes LD2a, LD2b, and LD2c. The first light-emitting diode LD1a (e.g., a first red light-emitting diode), the second light-emitting diode LD2a (e.g., a second red light-emitting diode), the first light-emitting diode LD1b (e.g., a first green light-emitting diode), the second light-emitting diode LD2b (e.g., a second green light-emitting diode), the first light-emitting diode LD1c (e.g., a first blue light-emitting diode), and the second light-emitting diode LD2c (e.g., a second blue light-emitting diode) are arranged in a single column without a specific order.

For example, the first light-emitting diode LD1a, the second light-emitting diode LD2a, the first light-emitting diode LD1b, the second light-emitting diode LD2b, the first light-emitting diode LD1c, and the second light-emitting diode LD2c are arranged in a single column along the first direction D1.

Referring to FIG. 9B, the circuit structure includes multiple first bonding pads 282a and 282b and multiple second bonding pads 284a and 284b. A portion of the first bonding pads 282a and 282b (i.e., the first bonding pad 282a) is connected to a portion of the second bonding pads 284a and 284b (i.e., the second bonding pad 284a) to form a shared bonding pad CP. Another portion of the first bonding pads 282a and 282b (i.e., the first bonding pad 282b) and another portion of the second bonding pads 284a and 284b (i.e., the second bonding pad 284b) are separated and arranged in a single column.

The first light-emitting diodes LD1a, LD1b, and LD1c are respectively bonded to corresponding ones of the first bonding pads 282b, and the second light-emitting diodes LD2a, LD2b, and LD2c are respectively bonded to corresponding ones of the second bonding pads 284b. The first light-emitting diodes LD1a, LD1b, and LD1c and the second light-emitting diodes LD2a, LD2b, and LD2c are all bonded to the shared bonding pad CP.

The distance S1 between the two first bonding pads 282a and 282b bonded to the same first light-emitting diode LD1a, LD1b, LD1c and the distance S2 between the two second bonding pads 284a and 284b bonded to the same second light-emitting diode LD2a, LD2b, LD2c may be the same or different. In a preferred embodiment, the distance S2 is greater than the distance S1, making it easier for the light emitted by the second light-emitting diodes LD2a, LD2b, and LD2c to pass through the circuit structure located beneath them.

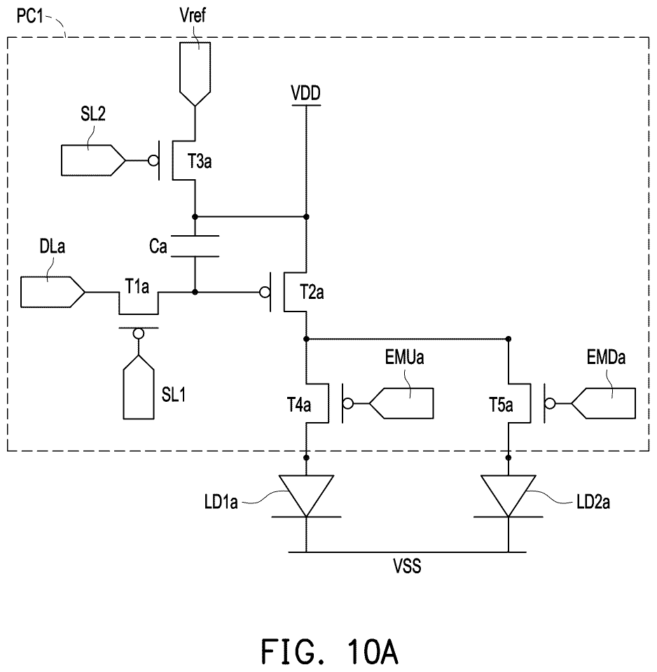

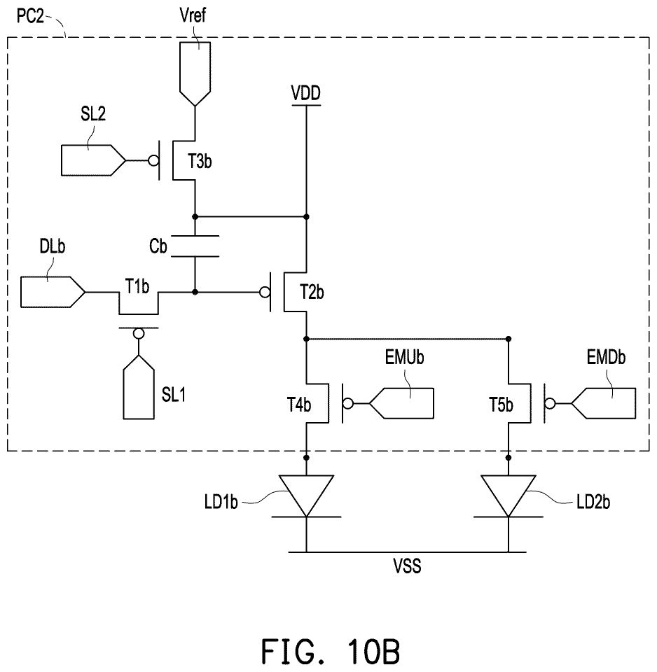

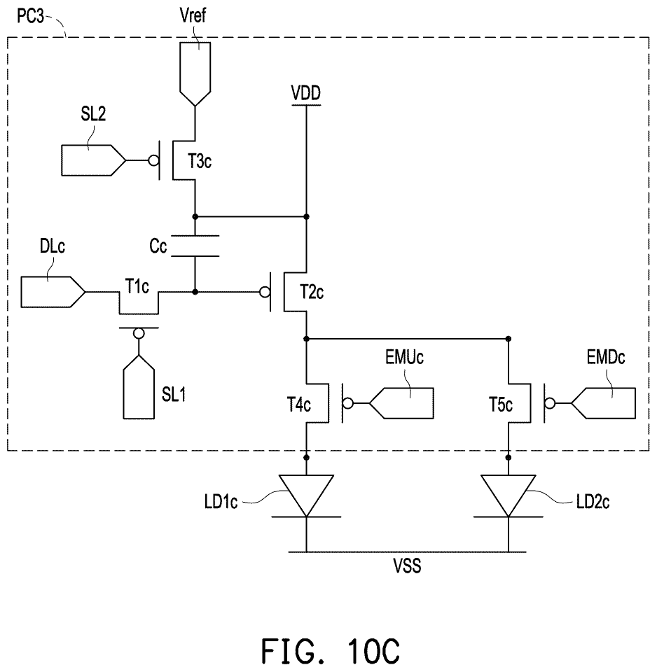

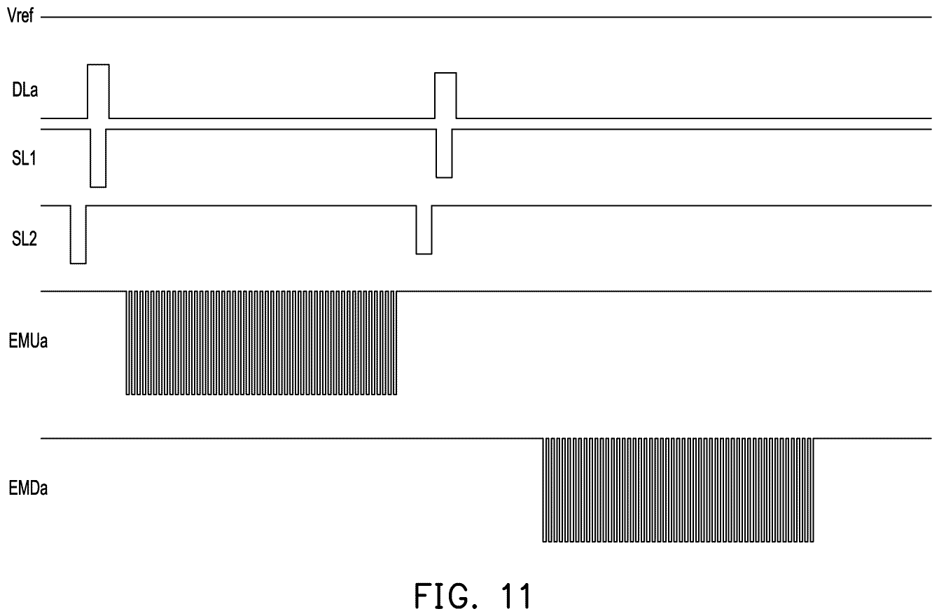

FIG. 10A is an equivalent circuit diagram of a first light-emitting diode, a second light-emitting diode, and a first pixel control circuit according to an embodiment of the disclosure. It should be noted that the embodiment in FIG. 10A adopts the element numerals and some content from any of the embodiments in FIGS. 1 to 9B, where the same or similar numerals denote the same or similar elements, and the description of identical technical content is omitted. For omitted descriptions, refer to the previously mentioned embodiments, which are not repeated here.

Referring to FIG. 10A, in this embodiment, the dual-sided display includes a circuit structure, a first light-emitting diode LD1a, and a second light-emitting diode LD2a. In some embodiments, the first light-emitting diode LD1a in the first pixel is configured to cause the second side of the dual-sided display to emit light, and the second light-emitting diode LD2a in the second pixel is configured to cause the first side of the dual-sided display to emit light.

The circuit structure includes a first scan line SL1, a second scan line SL2, a first data line DLa, a first light-emission signal line EMUa, a second light-emission signal line EMDa, a reference voltage signal line Vref, a first operating voltage signal line VDD, a second operating voltage signal line VSS, and the first pixel control circuit PC1.

The first pixel control circuit PC1 is used to drive the first light-emitting diode LD1a and the second light-emitting diode LD2a. In this embodiment, the first light-emitting diode LD1a and the second light-emitting diode LD2a, which display images on different sides, share the first data line DLa, the first scan line SL1, the second scan line SL2, the reference voltage signal line Vref, the first operating voltage signal line VDD, and the second operating voltage signal line VSS.

The first pixel control circuit PC1 includes a first switching transistor T1a, a first driving transistor T2a, a first auxiliary transistor T3a, a first capacitor Ca, a first light-emission control transistor T4a, and a second light-emission control transistor T5a.

The gate of the first switching transistor T1a is electrically connected to the first scan line SL1, and the first source/drain of the first switching transistor T1a is electrically connected to the first data line DLa.

The gate of the first auxiliary transistor T3a is electrically connected to the second scan line SL2, and the first source/drain of the first auxiliary transistor T3a is electrically connected to the reference voltage signal line Vref.

The first terminal of the first capacitor Ca is electrically connected to the second source/drain of the first auxiliary transistor T3a, the first source/drain of the first driving transistor T2a, and the first operating voltage signal line VDD. The second terminal of the first capacitor Ca is electrically connected to the second source/drain of the first switching transistor T1a and the gate of the first driving transistor T2a.

The second source/drain of the first driving transistor T2a is electrically connected to the first source/drain of the first light-emission control transistor T4a and the first source/drain of the second light-emission control transistor T5a. The gate of the first light-emission control transistor T4a and the gate of the second light-emission control transistor T5a are electrically connected to the first light-emission signal line EMUa and the second light-emission signal line EMDa, respectively.

The second source/drain of the first light-emission control transistor T4a and the second source/drain of the second light-emission control transistor T5a are electrically connected to the first light-emitting diode LD1a and the second light-emitting diode LD2a, respectively. The first light-emitting diode LD1a and the second light-emitting diode LD2a are electrically connected to the second operating voltage signal line VSS.

FIG. 11 is a timing diagram of a method for driving a light-emitting diode according to an embodiment of the disclosure. Referring to FIGS. 10A and 11, the first light-emitting diode LD1a and the second light-emitting diode LD2a are illuminated at different times through different first light-emission signal line EMUa and the second light-emission signal line EMDa. During the operation of the first pixel control circuit PC1, the reference voltage signal line Vref maintains an equipotential state.

As shown in FIG. 11, first, the second scan line SL2 provides a signal (e.g., referred to as a reset signal) to the first auxiliary transistor T3a.

Next, the first scan line SL1 is used to turn on the first switching transistor T1a, and the first data signal is written into the first pixel control circuit PC1 through the first data line DLa.

Then, the first light-emission signal line EMUa is used to turn on the first light-emission control transistor T4a, thereby illuminating the first light-emitting diode LD1a. At this time, the second light-emission control transistor T5a remains in the off state.

Next, the second scan line SL2 is again used to provide a signal (e.g., referred to as a reset signal) to the first auxiliary transistor T3a.

Subsequently, the first scan line SL1 is again used to turn on the first switching transistor T1a, and the second data signal is written into the first pixel control circuit PC1 through the first data line DLa.

Finally, the second light-emission signal line EMDa is used to turn on the second light-emission control transistor T5a, thereby illuminating the second light-emitting diode LD2a. At this time, the first light-emission control transistor T4a remains in the off state.

Through the above method, the first light-emitting diode LD1a and the second light-emitting diode LD2a may be sequentially illuminated.

In some embodiments, the first light-emitting diode LD1a and the second light-emitting diode LD2a are respectively a first red light-emitting diode and a second red light-emitting diode, and the first pixel further includes a first light-emitting diode LD1b (e.g., a first green light-emitting diode) and a first light-emitting diode LD1c (e.g., a first blue light-emitting diode), while the second pixel further includes a second light-emitting diode LD2b (e.g., a second green light-emitting diode) and a second light-emitting diode LD2c (e.g., a second blue light-emitting diode), as shown in FIGS. 10B and 10C.

In some embodiments, referring to FIGS. 10B and 10C, the circuit structure further includes a second pixel control circuit PC2 electrically connected to the first light-emitting diode LD1b and the second light-emitting diode LD2b, and a third pixel control circuit PC3 electrically connected to the first light-emitting diode LD1c and the second light-emitting diode LD2c.

The circuit structure includes a second data line DLb, a third data line DLc, a third light-emission signal line EMUb, a fourth light-emission signal line EMDb, a fifth light-emission signal line EMUc, and a sixth light-emission signal line EMDc. In some embodiments, the first pixel control circuit PC1, the second pixel control circuit PC2, and the third pixel control circuit PC3 share the first scan line SL1 and the second scan line SL2.

The second pixel control circuit PC2 is used to drive the first light-emitting diode LD1b and the second light-emitting diode LD2b, while the third pixel control circuit PC3 is used to drive the first light-emitting diode LD1c and the second light-emitting diode LD2c.

The second pixel control circuit PC2 includes a second switching transistor T1b, a second driving transistor T2b, a second auxiliary transistor T3b, a second capacitor Cb, a third light-emission control transistor T4b, and a fourth light-emission control transistor T5b. The third pixel control circuit PC3 includes a third switching transistor T1c, a third driving transistor T2c, a third auxiliary transistor T3c, a third capacitor Cc, a fifth light-emission control transistor T4c, and a sixth light-emission control transistor T5c.

The driving methods for the second pixel control circuit PC2 and the third pixel control circuit PC3 are similar to the driving method for the first pixel control circuit PC1 shown in FIGS. 10A and 11, and the related descriptions are not repeated here.

In summary, in the dual-sided display of the disclosure, the second light-emitting diode configured to cause the dual-sided display to emit light from the first side and the first light-emitting diode configured to cause the dual-sided display to emit light from the second side share the same pixel control circuit. This arrangement saves space in the circuit layout and enables the dual-sided display to efficiently display images on opposite sides.

What is claimed is:

1. A dual-sided display, comprising:
a first substrate;
a circuit structure, formed on the first substrate and comprising:
a first pixel control circuit, comprising:
a driving transistor; and
a first light-emission control transistor and a second light-emission control transistor, electrically connected to the driving transistor;
a first pixel, comprising:
a first light-emitting diode, bonded to the circuit structure and electrically connected to the first light-emission control transistor; and
a second pixel, comprising:
a second light-emitting diode, bonded to the circuit structure and electrically connected to the second light-emission control transistor, wherein the second pixel is configured to cause the dual-sided display to emit a light from a first side, and the first pixel is configured to cause the dual-sided display to emit the light from a second side opposite to the first side.

2. The dual-sided display according to claim 1, further comprising:
a second substrate, overlapping the first substrate; and
a reflective layer, formed on the second substrate, wherein the reflective layer is configured to reflect a light emitted toward the second substrate by the second light-emitting diode, and the circuit structure is configured to at least partially shield a light emitted toward the first substrate by the first light-emitting diode.

3. The dual-sided display according to claim 2, further comprising:
an isolation structure, formed on the second substrate, wherein the first pixel and the second pixel are surrounded by the isolation structure.

4. The dual-sided display according to claim 3, wherein the circuit structure comprises a first light-shielding layer, the first light-shielding layer being located between the first substrate and the isolation structure and having a plurality of first openings, wherein the plurality of first openings respectively overlap the first light-emitting diode and the second light-emitting diode, the dual-sided display further comprising:
a second light-shielding layer, located between the isolation structure and the second substrate and having a second opening, the second opening overlapping the first light-emitting diode.

5. The dual-sided display according to claim 4, wherein the second light-shielding layer extends between the reflective layer and the second substrate, and the second light-shielding layer overlaps the reflective layer and the second light-emitting diode.

6. The dual-sided display according to claim 1, wherein the first light-emitting diode is bonded to two first bonding pads of the circuit structure, and the second light-emitting diode is bonded to two second bonding pads of the circuit structure, wherein one or a plurality of shielding structures in the circuit structure overlap a gap between the two first bonding pads in a normal direction of a top surface of the first substrate, and a gap between the two second bonding pads overlaps a transparent region of the circuit structure.

7. The dual-sided display according to claim 1, wherein the first light-emitting diode is bonded to two first bonding pads of the circuit structure, and the second light-emitting diode is bonded to two second bonding pads of the circuit structure, wherein a distance between the two first bonding pads is less than a distance between the two second bonding pads.

8. The dual-sided display according to claim 7, wherein a ratio of the distance between the two second bonding pads to a length of the second light-emitting diode is less than 1 and greater than 0.3.

9. The dual-sided display according to claim 1, wherein the circuit structure further comprises:
a shielding layer, located on the first substrate, wherein the shielding layer comprises a metal layer and a covering layer, the covering layer being located on a side of the metal layer facing the first substrate, wherein a material of the covering layer comprises one or more of NbSiCOx, CrOx, TiOx, and MoOxTa.

10. The dual-sided display according to claim 1, wherein the first light-emitting diode is a first red light-emitting diode, the second light-emitting diode is a second red light-emitting diode, the first pixel further comprises a first green light-emitting diode and a first blue light-emitting diode, the second pixel further comprises a second green light-emitting diode and a second blue light-emitting diode, and the circuit structure further comprises a second pixel control circuit electrically connected to the first green light-emitting diode and the second green light-emitting diode and a third pixel control circuit electrically connected to the first blue light-emitting diode and the second blue light-emitting diode.

11. The dual-sided display according to claim 10, wherein a size of the first red light-emitting diode is different from a size of the second red light-emitting diode, a size of the first green light-emitting diode is different from a size of the second green light-emitting diode, and/or a size of the first blue light-emitting diode is different from a size of the second blue light-emitting diode.

12. The dual-sided display according to claim 10, wherein the first red light-emitting diode is adjacent to the second red light-emitting diode, the first green light-emitting diode is adjacent to the second green light-emitting diode, and the first blue light-emitting diode is adjacent to the second blue light-emitting diode.

13. The dual-sided display according to claim 10, wherein the first red light-emitting diode, the second red light-emitting diode, the first green light-emitting diode, the second green light-emitting diode, the first blue light-emitting diode, and the second blue light-emitting diode are staggeredly arranged without a specific order.

14. The dual-sided display according to claim 13, wherein the circuit structure comprises a plurality of first bonding pads and a plurality of second bonding pads, wherein a portion of the plurality of first bonding pads are connected with a portion of the plurality of second bonding pads to form a shared bonding pad, and another portion of the plurality of first bonding pads and another portion of the plurality of second bonding pads are distributed on two sides of the shared bonding pad, wherein the first red light-emitting diode, the first green light-emitting diode, and the first blue light-emitting diode are respectively bonded to a corresponding one of the another portion of the plurality of first bonding pads, and the second red light-emitting diode, the second green light-emitting diode, and the second blue light-emitting diode are respectively bonded to a corresponding one of the another portion of the plurality of second bonding pads, and wherein the first red light-emitting diode, the second red light-emitting diode, the first green light-emitting diode, the second green light-emitting diode, the first blue light-emitting diode, and the second blue light-emitting diode are bonded to the shared bonding pad.

15. The dual-sided display according to claim 10, wherein the first red light-emitting diode, the second red light-emitting diode, the first green light-emitting diode, the second green light-emitting diode, the first blue light-emitting diode, and the second blue light-emitting diode are arranged in a single column without a specific order.

16. The dual-sided display according to claim 15, wherein the circuit structure comprises a plurality of first bonding pads and a plurality of second bonding pads, wherein a portion of the plurality of first bonding pads are connected with a portion of the plurality of second bonding pads to form a shared bonding pad, and another portion of the plurality of first bonding pads and another portion of the plurality of second bonding pads are separated and arranged in a single column, wherein the first red light-emitting diode, the first green light-emitting diode, and the first blue light-emitting diode are respectively bonded to a corresponding one of the another portion of the plurality of first bonding pads, and the second red light-emitting diode, the second green light-emitting diode, and the second blue light-emitting diode are respectively bonded to a corresponding one of the another portion of the plurality of second bonding pads, and wherein the first red light-emitting diode, the second red light-emitting diode, the first green light-emitting diode, the second green light-emitting diode, the first blue light-emitting diode, and the second blue light-emitting diode are bonded to the shared bonding pad.

17. The dual-sided display according to claim 1, wherein the dual-sided display is a transparent display comprising a plurality of transmission regions, wherein adjacent four of the plurality of transmission regions surround the first pixel and the second pixel.

18. The dual-sided display according to claim 1, wherein the first pixel control circuit further comprises:
a switching transistor, wherein a gate of the switching transistor is electrically connected to a first scan line, and a first source/drain of the switching transistor is electrically connected to a data line;
an auxiliary transistor, wherein a gate of the auxiliary transistor is electrically connected to a second scan line, and a first source/drain of the auxiliary transistor is electrically connected to a reference voltage signal line;
a capacitor, wherein a first terminal of the capacitor is electrically connected to a second source/drain of the auxiliary transistor, a first source/drain of the driving transistor, and a first operating voltage signal line, and a second terminal of the capacitor is electrically connected to a second source/drain of the switching transistor and a gate of the driving transistor, wherein
a second source/drain of the driving transistor is electrically connected to a first source/drain of the first light-emission control transistor and a first source/drain of the second light-emission control transistor, and a second source/drain of the first light-emission control transistor and a second source/drain of the second light-emission control transistor are respectively electrically connected to the first light-emitting diode and the second light-emitting diode.

19. A manufacturing method of a dual-sided display, comprising:
forming a circuit structure on a first substrate, wherein the circuit structure comprises a first pixel control circuit, the first pixel control circuit comprising a driving transistor and a first light-emission control transistor and a second light-emission control transistor electrically connected to the driving transistor;
transferring a first light-emitting diode and a second light-emitting diode to the circuit structure, wherein the first light-emitting diode and the second light-emitting diode are respectively electrically connected to the first light-emission control transistor and the second light-emission control transistor;
forming a second light-shielding layer on a second substrate;
forming a reflective layer on the second substrate; and
bonding the first substrate to the second substrate using an encapsulation layer, wherein the second light-emitting diode is configured to cause the dual-sided display to emit a light from a first side, and the first light-emitting diode is configured to cause the dual-sided display to emit the light from a second side opposite to the first side.

20. The manufacturing method of the dual-sided display according to claim 19, further comprising:
forming an isolation structure on the second substrate and the second light-shielding layer, wherein, after bonding the first substrate to the second substrate, the first pixel and the second pixel are surrounded by the isolation structure.
